(19) United States
(12) Patent Application Publication
(10) Pub. No.: US 2026/0058227 A1
(43) Pub. Date: Feb. 26, 2026

(54) RECHARGEABLE BATTERY

(71) Applicant: SAMSUNG SDI CO., LTD., Yongin-si (KR)

(72) Inventor: BONGKOUN JANG, Yongin-si (KR)

(21) Appl. No.: 19/271,990

(22) Filed: Jul. 17, 2025

(30) Foreign Application Priority Data
Aug. 22, 2024 (KR) 10-2024-0112989

(51) Int. Cl. H01M 10/42; H01M 10/653; H01M 50/519

(52) U.S. Cl. CPC H01M 10/425; H01M 10/653; H01M 50/519; H01M 2200/00

(57) ABSTRACT

A rechargeable battery includes a battery cell, a terrace extending from the battery cell, a protection circuit module on the terrace, and a heat dissipation sheet covering the protection circuit module, wherein the heat dissipation sheet includes a heat dissipation portion dissipating heat generated by the protection circuit module, and a short-circuit prevention portion within the heat dissipation portion.

### CROSS-REFERENCE TO RELATED APPLICATION

This application claims priority to and the benefit of Korean Patent Application No. 10-2024-0112989 filed at the Korean Intellectual Property Office on Aug. 22, 2024, the entire contents of which are incorporated herein by reference.

### BACKGROUND

### 1 Field

The present disclosure relates to a rechargeable battery.

### 2. Description of the Related Art

In general, as demand for a portable electronic product such as a laptop, a video camera, and a portable phone rapidly increases and a robot, an electric vehicle, or the like becomes commercially available, research on a rechargeable battery capable of being repeatedly charged and discharged is actively being conducted.

The rechargeable battery may include a battery cell for supplying electric power and a protection circuit module (PCM) that is electrically connected to the battery cell to continuously detect and control a value such as a voltage, a current, or a temperature.

The above-described information disclosed in the technology that is the background of this disclosure is only for improving understanding of the background of the present disclosure, and thus may include the information that does not constitute the prior art.

### SUMMARY

Embodiments include a rechargeable battery, including a battery cell, a terrace extending from the battery cell, a protection circuit module on the terrace, and a heat dissipation sheet covering the protection circuit module, wherein the heat dissipation sheet includes a heat dissipation portion dissipating heat generated by the protection circuit module, and a short-circuit prevention portion within the heat dissipation portion.

The protection circuit module may include a substrate including a first surface facing the terrace and a second surface opposite to the first surface, a lead connection plate on the first surface, and a transistor on the second surface.

The battery cell may further include an electrode lead, and the electrode lead may be connected to the lead connection plate.

One end of the electrode lead and one end of the lead connection plate may coincide with an extension line of a side surface of the substrate.

The short-circuit prevention portion may face the one end of the electrode lead and the one end of the lead connection plate.

The protection circuit module may further comprise a molding member on the second surface, the molding member surrounding the transistor.

The molding member may include a molding surrounding the transistor, the molding body may include a fixing surface fixed to the substrate, a first heat dissipation surface on an opposite side of the fixing surface and facing the heat dissipation sheet, and a second heat dissipation surface connecting the fixing surface to the first heat dissipation surface, the second heat dissipation surface facing the heat dissipation sheet.

The heat dissipation portion may include a first heat dissipation portion facing the first heat dissipation surface, a second heat dissipation portion facing the second heat dissipation surface, a third heat dissipation portion facing the side surface of the substrate, and a fourth heat dissipation portion in contact with an outer surface of the terrace.

The first heat dissipation portion, the second heat dissipation portion, the third heat dissipation portion, and the fourth heat dissipation portion may be continuously connected.

The first heat dissipation portion, the second heat dissipation portion, the third heat dissipation portion, and the fourth heat dissipation portion may form a C-shape.

The heat dissipation sheet may include a heat conductive layer including a heat conductive material, an insulating layer on an inner surface of the heat conductive layer, the insulating layer facing the protection circuit module, and a protective layer on an outer surface of the heat conductive layer.

The short-circuit prevention portion may include an opening in the heat conductive layer.

The short-circuit prevention portion may include a single slit with a rectangular shape in the heat conductive layer.

The short-circuit prevention portion may include a plurality of slits in a rectangular shape, the plurality of slits being in the heat conductive layer.

A fusible link may be between the plurality of slits.

The protective layer may include a flame-retardant layer comprising a flame-retardant material, and an adhesive layer between the flame-retardant layer and the heat conductive layer.

The insulating layer may have a first thickness and the protective layer has a second thickness thicker than the first thickness.

The heat dissipation sheet may further include a first fixing end portion fixed to the battery cell, and a second fixing end portion fixed to the terrace.

The heat dissipation portion may include the heat conductive layer, the insulating layer, and the protective layer, and the first fixing end portion and the second fixing end portion may include the insulating layer and the protective layer.

The heat dissipation portion may have a rectangular shape

### BRIEF DESCRIPTION OF THE DRAWINGS

Features will become apparent to those of ordinary skill in the art by describing in detail exemplary embodiments with reference to the attached drawings, in which:

FIG. 1 is a perspective view schematically showing a rechargeable battery according to one or more embodiments of the present disclosure;

FIG. 2 is a main portion exploded perspective view schematically showing the rechargeable battery according to FIG. 1;

FIG. 3 is a cross-sectional view of one or more embodiments taken along a line A-A′ in FIG. 1;

FIG. 4 is a view schematically showing a state in which a heat dissipation sheet is unfolded according to one or more embodiments of the present disclosure;

FIG. 5 is a cross-sectional view of one or more embodiments taken along a line B-B′ in FIG. 4;

FIG. 6 is a conceptual view showing short-circuit prevention of the heat dissipation sheet according to one or more embodiments of the present disclosure;

FIG. 7 is a view schematically showing a state in which the heat dissipation sheet is unfolded according to one or more other embodiments of the present disclosure; and

FIG. 8 is a view schematically showing a state in which the heat dissipation sheet is unfolded according to one or more other embodiments of the present disclosure.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Embodiments of the present disclosure will be described more fully hereinafter with reference to the accompanying drawings so that those skilled in the art could easily implement the embodiments. The present disclosure may be modified in various ways, all without departing from the spirit or scope of the present disclosure.

In order to clearly describe the present disclosure, parts or portions that are irrelevant to the description are omitted.

In the drawings, a size and a thickness of each element are arbitrarily illustrated for ease of description, and the present disclosure is not necessarily limited to those illustrated in the drawings. In the drawings, the thicknesses of some layers and areas are exaggerated for clarity.

It should be understood that when an element such as a layer, a film, a region, or a plate is referred to as being “on” or “above” another element, it may be directly on the other element, or an intervening element may also be present. In contrast, when an element is referred to as being “directly on” another element, there is no intervening element present. Further, in the specification, the word “on” or “above” means disposed on or below a referenced part, and does not necessarily mean disposed on the upper side of the referenced part based on a gravitational direction.

Unless explicitly stated to the contrary, the word “comprise” and variations such as “comprises” and “comprising” should be understood to imply the inclusion of stated elements but not the exclusion of any other elements.

Throughout the specification, the phrase “in a plan view” or “on a plane” may mean when an object portion is viewed from above, and the phrase “in a cross-sectional view” or “on a cross-section” may mean when a cross-section taken by vertically cutting an object portion is viewed from the side.

In the drawing, the symbols “X”, “Y”, and “Z” may be used to indicate a direction. Here, “X” may be a first direction, “Y” may be a second direction perpendicular to the first direction, and “Z” may be a third direction perpendicular to the first direction and the second direction. The X-axis direction (e.g., the first direction) may correspond to a horizontal direction or a left-right direction of a rechargeable battery. The Y-axis direction (e.g., the second direction) may correspond to a vertical direction or a length direction of the rechargeable battery. The Z-axis direction (e.g., the third direction) may correspond to a thickness direction, a height direction, or a vertical direction of the rechargeable battery.

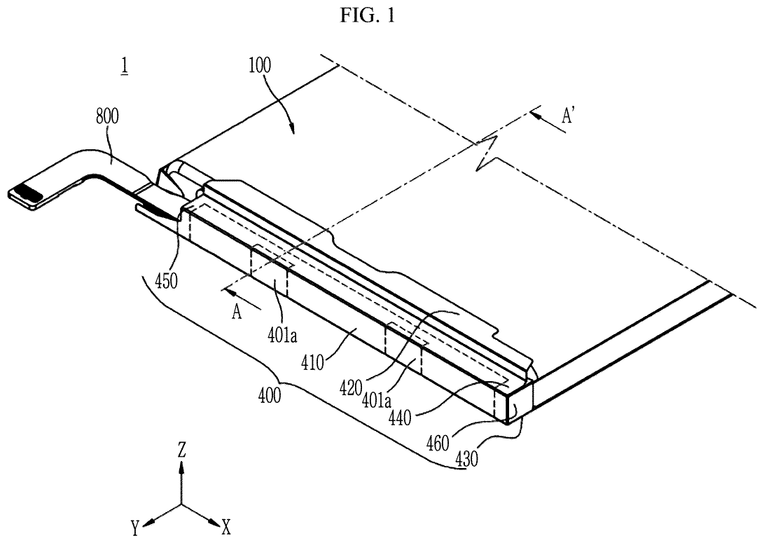

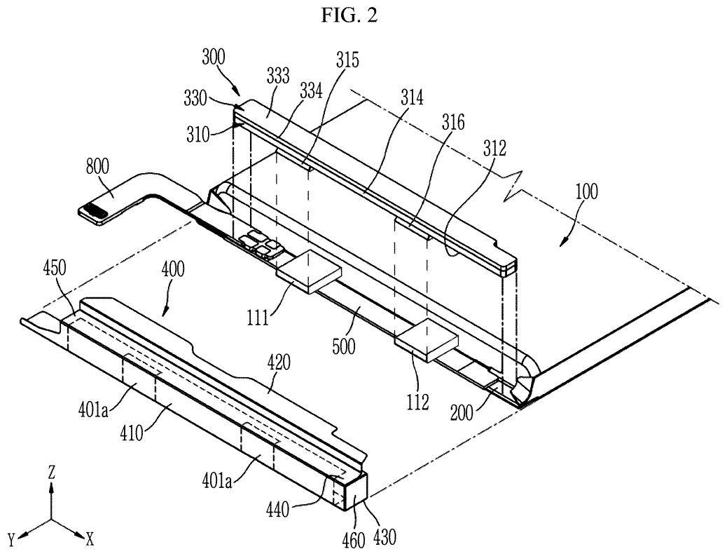

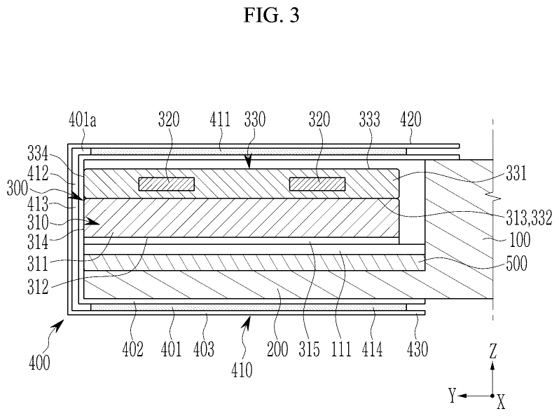

FIG. 1 is a perspective view schematically showing components of a rechargeable battery according to one or more embodiments of the present disclosure, FIG. 2 is a main portion exploded perspective view schematically showing the components of the rechargeable battery according to FIG. 1, and FIG. 3 is a cross-sectional view of one or more embodiments taken along a line A-A′ in FIG. 1.

Referring to FIGS. 1 to 3, the rechargeable battery 1 according to one or more embodiments may include a battery cell 100, a terrace 200, a protection circuit module 300, and a heat dissipation sheet 400.

The battery cell 100 may be a unit structure storing and supplying electric power, and for example, it may be a lithium rechargeable battery capable of charging and discharging a predetermined amount of electric power. For example, the battery cell 100 according to the present embodiment may be a pouch-type battery cell including an electrode assembly and an exterior material surrounding the electrode assembly. Electrode leads 111 and 112 may be disposed on one side of the battery cell 100.

The electrode assembly may be formed in a winding type in which a first electrode plate, a second electrode plate, and a separator interposed between the first and second electrode plates are wound in a roll shape, or may be formed in a stacking type in which a first electrode plate, a second electrode plate, and a separator are stacked on each other.

The electrode leads 111 and 112 may include a positive electrode lead 111 and a negative electrode lead 112, and may protrude from one side of the battery cell 100 in the Y-axis direction (e.g., the second direction).

The terrace 200 may extend from the battery cell 100, and may support the protection circuit module 300. The terrace 200 according to the present embodiment may have a plate shape extending horizontally in the Y-axis direction (e.g., the second direction) of the battery cell 100 from an end portion surface of the battery cell 100. The terrace 200 may be integrally formed with the battery cell 100, or may be manufactured separately from the battery cell 100 and then may be coupled to the battery cell 100. A lower surface of the terrace 200 may be disposed to be spaced apart from the battery cell 100 by a predetermined interval.

The protection circuit module 300 may be disposed above the terrace 200 to face the terrace 200, and may be electrically connected to the battery cell 100. The protection circuit module 300 may form paths of a charging current and a discharging current of the battery cell 100, or may perform a protection operation for preventing overheating of the battery cell 100 or explosion of the battery cell 100 caused by overcharging, overdischarging, or the like.

The protection circuit module 300 may have a structure in which a substrate 310, a field effect transistor (FET) 320, and a molding member 330 are integrally coupled.

The substrate 310 may include a substrate body 311 with a flat plate shape having a first surface 312 and a second surface 313 opposite to each other. The first surface 312 may be disposed to face downward based on the drawings so that it is disposed to face an upper surface of the terrace 200. The second surface 313 of the substrate 310 may be disposed to face upward based on the drawings so that it is disposed to face a space on the terrace 200.

The substrate body 311 may further include a third surface 314 and a fourth surface that are disposed to face the first and second surfaces 312 and 313 while being perpendicular to the first and second surfaces 312 and 313. The substrate body 311 may have a rectangular hexahedral shape that corresponds to the terrace 200 as a whole and has a horizontal width (e.g., a width along the X axis direction (e.g., the first direction)) and a vertical width (e.g., a width along the Y-axis direction (e.g., the second direction)). The first surface 312 and the second surface 313 may have a rectangular shape as a whole.

The third surface 314 may be disposed to face the outside of the battery cell 100 so that it has a flat surface in surface contact with the heat dissipation sheet 400. For example, facing the outside of the battery cell 100 may mean facing in a direction opposite to a direction facing the inside of the battery cell 100. The third surface 314 may have an area formed by a thickness (e.g., a width along the Z-axis direction (e.g., the third direction) perpendicular to the first and second directions) of the substrate body 311 and a horizontal width (e.g., a width in the X-axis direction (e.g., the first direction)).

An electronic element may be mounted on the second surface 313 of the substrate 310 to form paths of a charging current and a discharging current of the battery cell 100 or perform a protection operation for preventing overheating of the battery cell 100 or explosion of the battery cell 100 caused by overcharging, overdischarging, or the like. The electronic element may include the field effect transistor (FET) 320 controlling a flow of a current through a semiconductor material using an electric field. For example, a metal-oxide-semiconductor field effect transistor (MOSFET) may be used as the field effect transistor 320.

Lead connection plates 315 and 316 may be disposed on the first surface 312 of the substrate 310. The lead connection plates 315 and 316 may include the positive electrode lead connection plate 315 and the negative electrode lead connection plate 316. The positive electrode lead connection plate 315 may be connected to the positive electrode lead 111, and the negative electrode lead connection plate 316 may be connected to the negative electrode lead 112. The positive electrode lead connection plate 315 and the positive electrode lead 111 may extend in the Y-axis direction (e.g., the second direction) so that one end of the positive electrode lead connection plate 315 and one end of the positive electrode lead 111 coincide with an extension line of the third surface 314. The negative electrode lead connection plate 316 and the negative electrode lead 112 may extend in the Y-axis direction (e.g., the second direction) so that one end of the negative electrode lead connection plate 316 and one end of the negative electrode lead 112 coincide with the extension line of the third surface 314.

The molding member 330 may be disposed on the second surface 313 to cover the field effect transistor 320 or to bury the field effect transistor 320 therein. The molding member 330 may include a molding body 331 surrounding the field effect transistor 320. An outer surface of the molding body 331 may include a fixing surface 332, a first heat dissipation surface 333, and a second heat dissipation surface 334.

The molding body 331 may extend in the X-axis direction (e.g., the first direction) along the substrate 310, and may have a thickness (e.g., a width in the Z-axis direction (e.g., the third direction)) capable of covering an electronic element including the field effect transistor 320. The molding body 331 may have a rectangular hexahedral shape that corresponds to an upper surface (i.e., the second surface 313) of the substrate 310 as a whole and has a horizontal width (e.g., a width in the X-axis direction (e.g., the first direction)) and a vertical width (e.g., a width in the Y-axis direction (e.g., the second direction)).

The molding body 331 may be formed with various molding materials and molding methods, and the molding body 331 may include epoxy or the like.

The fixing surface 332 may be disposed on a bottom surface of the molding body 331 to be fixed to the second surface 313 of the substrate 310. The fixing surface 332 may be formed by melting a molding material forming the molding body 331 and adhering the molding material to the second surface 313. The fixing surface 332 may have a rectangular shape corresponding to the second surface 313 as a whole, and may be integrally coupled to the entire second surface 313.

The molding member 330 may surround and protect the entire plurality of electronic elements including a circuit formed above the second surface 313 and the field effect transistor 320 mounted above the second surface 313 using the molding body 331, and it may be stably fixed and maintained at a set position on the second surface 313 by the fixing surface 332.

The first heat dissipation surface 333 may be disposed on an opposite side of the fixing surface 332 (i.e., an upper surface of the molding body 331) to face the heat dissipation sheet 400. The fixing surface 332 and the first heat dissipation surface 333 may have a rectangular shape that corresponds to the upper surface (i.e., the second surface 313) of the substrate 310 as a whole and may have a horizontal width (e.g., a width in the X-axis direction (e.g., the first direction)) and a vertical width (e.g., a width in the Y-axis direction (e.g., the second direction)).

The first heat dissipation surface 333 may have a flat surface in surface contact with the heat dissipation sheet 400. For example, the flat surface may mean a continuous contact surface in surface contact with the heat dissipation sheet 400. The first heat dissipation surface 333 may have a rectangular shape as a whole, and a portion of the rectangular shape may be formed to be round. A protruding portion or a groove portion may be formed at a portion of the first heat dissipation surface 333.

The second heat dissipation surface 334 may be formed on an outer side surface of the molding body 331 facing the outside of the battery cell 100 to contact the heat dissipation sheet 400. The second heat dissipation surface 334 may connect the fixing surface 332 and the first heat dissipation surface 333. The second heat dissipation surface 334 may have an area formed by a thickness (e.g., a width in the Z-axis direction (e.g., the third direction)) of the molding body 331 and a horizontal width (e.g., a width in the X-axis direction (e.g., the first direction)). The second heat dissipation surface 334 may form a flat surface to be in surface contact with the heat dissipation sheet 400. The second heat dissipation surface 334 may form the flat surface that is continuous with the third surface 314 of the substrate 310 to be in surface contact with the heat dissipation sheet 400.

The heat dissipation sheet 400 may sequentially face the first heat dissipation surface 333 and the second heat dissipation surface 334 of the molding member 330 and the third surface 314 of the substrate 310 from an upper side thereof, so that heat generated from an electronic element such as the field effect transistor 320 mounted on the substrate 310 is transferred to the heat dissipation sheet 400 through the first heat dissipation surface 333, the second heat dissipation surface 334, and the third surface 314.

The heat dissipation sheet 400 may have a thin film shape, and may include an insulating layer 402, a protective layer 403, and a heat conductive layer 401 disposed between the insulating layer 402 and the protective layer 403. The heat conductive layer 401 may include a heat conductive material.

The heat dissipation sheet 400 may be disposed outside the battery cell 100 to surround the protection circuit module 300. The heat dissipation sheet 400 including the heat conductive material may dissipate heat generated from the protection circuit module 300 across the entire surface thereof. For example, the heat dissipation sheet 400 may perform a function of protecting the protection circuit module 300 from an external foreign substance or the like.

As shown in FIG. 3, the heat dissipation sheet 400 may be in contact with only a portion of the protection circuit module 300. For example, the heat dissipation sheet 400 may be in contact with the second heat dissipation surface 334 of the molding member 330, and may be disposed to be spaced apart from the first heat dissipation surface 333. The heat dissipation sheet 400 may be disposed to be in contact with both the first heat dissipation surface 333 and the second heat dissipation surface 334 of the molding member 330.

In the rechargeable battery 1 according to one or more embodiments of the present disclosure, the protection circuit module 300 may be seated on and coupled to an upper surface of the terrace 200 and a side surface of the battery cell 100 via a fixing tape 500 of FIG. 3 to be described later. The heat dissipation sheet 400 may be disposed or coupled to extend to a bottom surface of the terrace 200 while surrounding an upper surface portion and a side surface portion of the protection circuit module 300 exposed to an external space of the battery cell 100 in an approximately C-shape. For example, the protection circuit module 300 may have a structure in which two field effect transistors 320 are disposed above the second surface 313 of the substrate 310 and the molding member 330 surrounds the two field effect transistors 320 and is integrally coupled to the second surface 313 of the substrate 310.

Heat generated from the field effect transistor 320 may be transferred to the heat dissipation sheet 400 through the upper surface of the molding member 330 (i.e., the first heat dissipation surface 333), the side surface of the molding member 330 (i.e., the second heat dissipation surface 334), and the side surface (i.e., the third surface 314) of the substrate 310 that are in contact with the heat dissipation sheet 400.

Heat transferred from the protection circuit module 300 to the heat dissipation sheet 400 may be uniformly transferred and distributed throughout the heat dissipation sheet 400 along the heat conductive layer 401. For example, the heat generated from the field effect transistor 320 may not be concentrated and dissipated on only an upper portion and an upper side portion of the rechargeable battery 1, and the heat dissipation of the heat dissipation sheet 400 may be uniformly performed over an entire area thereof including a lower portion and a lower side portion of the rechargeable battery 1 by the heat dissipation sheet 400.

The rechargeable battery 1 according to the present embodiment may further include the fixing tape 500. The fixing tape 500 may have a sheet shape in which an adhesive material is applied on a surface thereof. The fixing tape 500 may be seated on an upper surface of the terrace 200, and an upper surface of the fixing tape 500 may be disposed to face the first surface 312 of the protection circuit module 300.

The fixing tape 500 may be disposed to face an electronic element mounted on the first surface 312 of the protection circuit module 300, and may be in direct contact with the electronic element. The adhesive material may be applied to the surface of the fixing tape 500, and the electronic element may be adhered to a surface of the adhesive region. Thus, the protection circuit module 300 may be stably fixed above the terrace 200 by an adhesive force between the adhesive region of the fixing tape 500 and the electronic element.

As shown in FIG. 1 and FIG. 2, the rechargeable battery 1 according to one or more embodiments may further include an extension member 800 extending to the outside of the battery cell 100. For example, the extension member 800 may be an electronic component electrically connected to the substrate 310, or another substrate member that electrically connects the battery cell 100 and an external substrate.

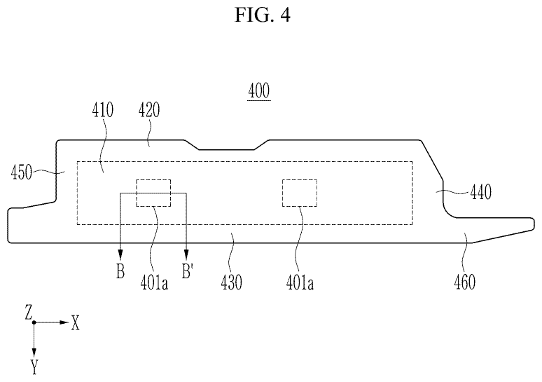

The protection circuit module 300 and the terrace 200 may have a rectangular hexahedral shape as a whole. If the heat conductive layer 401 and a heat dissipation portion 410 form an approximately C-shape along outer surfaces of the protection circuit module 300 and the terrace 200, a heat transfer and heat dissipation area may be ensured to be as wide as possible. The heat conductive layer 401 and the heat dissipation portion 410 may have a rectangular shape based on a development view shown in FIG. 4 to be described later.

Then, the heat dissipation sheet according to one or more embodiments of the present disclosure will be described in more detail with reference to FIGS. 1 to 3 together with FIGS. 4 to 6.

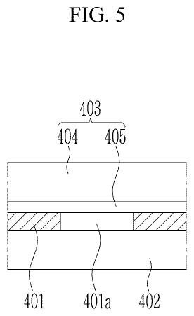

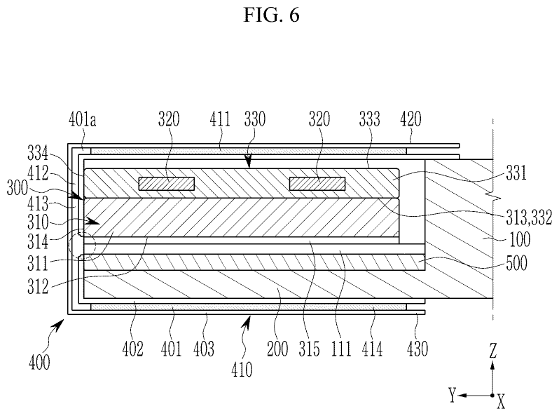

FIG. 4 is the development view schematically showing a state in which the heat dissipation sheet is unfolded according to one or more embodiments of the present disclosure, and FIG. 5 is a cross-sectional view of one or more embodiments taken along a line B-B′ in FIG. 4. FIG. 6 is a view showing short-circuit prevention of the heat dissipation sheet according to one or more embodiments of the present disclosure.

Referring to FIGS. 4 to 6, the heat dissipation sheet 400 according to the present embodiment may be formed by stacking and bonding the heat conductive layer 401, the insulating layer 402, and the protective layer 403. The heat conductive layer 401 may be interposed between the insulating layer 402 and the protective layer 403 so that the protective layer 403 is disposed at an outermost side. Thus, as shown in FIG. 3, the insulating layer 402, the heat conductive layer 401, and the protective layer 403 may be disposed close to the battery cell 100 in an order of the insulating layer 402, the heat conductive layer 401, and the protective layer 403.

The heat conductive layer 401 may be formed by including a heat conductive material. The heat conductive material of the heat conductive layer 401 may include graphite. The heat conductive layer 401 may have an opening 401a, and the opening 401a may be a short-circuit prevention portion to be described later.

The insulating layer 402 may be formed of an insulating material, and may be stacked and bonded to one surface of the heat conductive layer 401. The insulating layer 402 may be disposed to face the battery cell 100, the terrace 200, and the protection circuit module 300. The insulating material of the insulating layer 402 may include at least one of polyethylene terephthalate (PET), polypropylene (PP), polyimide (PI), polyethylene (PE), and aramid. The insulating layer 402 may be formed of the insulating material described above to safely insulate the protection circuit module 300 from other external electronic components or conductive materials.

The insulating layer 402 may have a sheet shape in which an adhesive material is applied on a portion or all of a surface thereof. The insulating layer 402 may have a double-sided tape structure. The heat dissipation sheet 400 may be firmly adhered and fixed to the battery cell 100 and the terrace 200 by the adhesive material of the insulating layer 402.

The protective layer 403 may be formed of a flame-retardant material, and may be stacked and bonded on the other surface of the heat conductive layer 401 that is an opposite side of the insulating layer 402. In a state where the heat dissipation sheet 400 is coupled to surround the protection circuit module 300 as shown in FIG. 1, the protective layer 403 may be exposed to the outside, and the insulating layer 402 may be disposed therein.

The protective layer 403 according to the present embodiment may include a flame-retardant layer 404 and an adhesive layer 405 (see FIG. 5). The flame-retardant layer 404 may be formed by including a flame-retardant material, and the adhesive layer 405 may be formed by including an adhesive material. The adhesive layer 405 may be disposed between the flame-retardant layer 404 and the heat conductive layer 401, and may adhere the flame-retardant layer 404 to the heat conductive layer 401.

The flame-retardant material of the flame-retardant layer 404 may include at least one of polyethylene terephthalate (PET), polypropylene (PP), polyimide (PI), polyethylene (PE), and aramid. The flame-retardant layer 404 made of the flame-retardant material may perform a function preventing the protection circuit module 300 from being directly exposed to a flame when a fire occurs. The protective layer 403 may have various thicknesses according to desired flame-retardant performance.

The insulating layer 402 and the protective layer 403 may have a ductility in which a corner portion or a stepped portion of the battery cell 100, the terrace 200, or the protection circuit module 300 may be flexibly bent. The insulating layer 402 may have a first thickness capable of insulating the protection circuit module 300 from the heat conductive layer 401. The protective layer 403 may have a second thickness that is thicker than the first thickness. Thus, the protective layer 403 may more safely protect the heat conductive layer 401 and the protection circuit module 300 against a flame and an external impact, and may be deformed to be stretched more than the insulating layer 402 at the corner portion or the stepped portion.

The heat dissipation sheet 400 may include the heat dissipation portion 410, the short-circuit prevention portion 401a, a first fixing end portion 420, and a second fixing end portion 430.

The heat dissipation portion 410 may be a portion (or a region) where the heat conductive layer 401 is disposed, and may be disposed at most positions to surround an outer surface of the protection circuit module 300 in a state where the heat dissipation sheet 400 is coupled to surround the protection circuit module 300 as shown in FIG. 1 (see a state of the heat dissipation portion 410 shown in FIG. 1 and FIG. 2). The heat dissipation portion 410 may continuously transfer heat across an entire region where the heat conductive layer 401 is disposed, so that heat generated in the protection circuit module 300 is dissipated to the outside of the heat dissipation sheet 400 through the heat dissipation portion 410.

The heat dissipation portion 410 according to embodiments of the present disclosure may have a structure in which a first heat dissipation portion 411, a second heat dissipation portion 412, and a third heat dissipation portion 413 are continuously connected. The first heat dissipation portion 411 may be disposed to face the first heat dissipation surface 333 disposed on an upper surface of the molding member 330, the second heat dissipation portion 412 may be disposed to face the second heat dissipation surface 334 disposed on an outer side surface of the molding member 330, and the third heat dissipation portion 413 may be disposed to face the third surface 314 disposed on an outer side surface of the substrate 310.

The heat dissipation portion 410 according to one or more embodiments of the present disclosure may further include a fourth heat dissipation portion 414 that is in contact with an outer surface of the terrace 200 (i.e., a bottom surface of the terrace 200). The fourth heat dissipation portion 414 may be continuously connected to the third heat dissipation portion 413. The first heat dissipation portion 411, the second heat dissipation portion 412, the third heat dissipation portion 413, and the fourth heat dissipation portion 414 may have an approximately C-shape in a state in which the heat dissipation sheet 400 surrounds the protection circuit module 300.

For example, heat generated in the field effect transistor 320 may reach the third surface 314 through a circuit line formed on the second surface 313 of the substrate 310, and then may pass through the molding body 331 of the molding member 330 to reach the first heat dissipation surface 333 and the second heat dissipation surface 334. The heat reaching the first heat dissipation surface 333, the second heat dissipation surface 334, and the third surface 314 of the molding member 330 may be each be transferred to the first heat dissipation portion 411, the second heat dissipation portion 412, and the third heat dissipation portion 413, and may be more uniformly distributed to be dissipated throughout the entire heat dissipation portion 410 including the fourth heat dissipation portion 414.

The heat dissipation portion 410 may have a rectangular shape having a width in the X-axis direction (e.g., the first direction) and a width in the Y-axis direction (e.g., the second direction). The first fixing end portion 420 may extend in the X-axis direction (e.g., the first direction) along one end portion in the Y-axis direction (e.g., the second direction) of the heat dissipation portion 410, and may be bonded and fixed to the battery cell 100. The second fixing end portion 430 may extend in the X-axis direction (e.g., the first direction) along an edge portion of the heat dissipation portion 410 from an opposite side in the Y-axis direction (e.g., the second direction) of the first fixing end portion 420, and may be bonded and fixed to the terrace 200.

The short-circuit prevention portion 401a may be disposed within the heat dissipation portion 410, and may be disposed to face one end of the positive electrode lead 111 and one end of the negative electrode lead 112. For example, the short-circuit prevention portion 401a may be disposed to face one end of the positive electrode lead connection plate 315 and one end of the negative electrode lead connection plate 316. The short-circuit prevention portion 401a may be disposed to face the second heat dissipation surface 334 disposed on the outer side surface of the molding member 330 and the third surface 314 disposed on the outer side surface of the substrate 310.

If the insulating layer 402 facing the one end of the positive electrode lead 111 and the one end of the positive electrode lead connection plate 315 is destroyed (see a circular display portion shown in FIG. 6) as shown in FIG. 6, an electric current of the positive electrode lead 111 and an electric current of the positive electrode lead connection plate 315 may be transferred to the heat conductive layer 401 so that a short circuit occurs. However, because the short-circuit prevention portion 401a is disposed at a portion facing the one end of the positive electrode lead 111 and the one end of the positive electrode lead connection plate 315 as in the present embodiment, the heat conductive layer 401 may not exist at the portion facing the one end of the positive electrode lead 111 and the one end of the positive electrode lead connection plate 315. Even if the insulating layer 402 of the portion facing the one end of the positive electrode lead 111 and the one end of the positive electrode lead connection plate 315 is destroyed, the current of the positive electrode lead 111 and the current of the positive electrode lead connection plate 315 may be prevented from being transferred to the heat conductive layer 401 so that the short circuit occurs. The short-circuit prevention portion 401a may be an opening of the heat conductive layer 401.

The first fixing end portion 420 and the second fixing end portion 430 may be formed by mutually stacking and bonding only the insulating layer 402 and the protective layer 403 excluding the heat conductive layer 401. Thus, the first fixing end portion 420 and the second fixing end portion 430 may have a thinner thickness, and may be more firmly adhered and attached to the battery cell 100 and the terrace 200.

The heat dissipation sheet 400 according to the present embodiment may further include a third fixing end portion 440 and a fourth fixing end portion 450. The third fixing end portion 440 may extend in the Y-axis direction (e.g., the second direction) along one end portion in the Z-axis direction (e.g., the third direction) of the heat dissipation portion 410, and both end portions in the Y-axis direction (e.g., the second direction) of the heat dissipation portion 410 may be integrally connected to the first fixing end portion 420 and the second fixing end portion 430. The fourth fixing end portion 450 may extend in the Y-axis direction (e.g., the second direction) along an edge portion of the heat dissipation portion 410 from an opposite side in the X-axis direction (e.g., the first direction) of the third fixing end portion 440, and both end portions in the Y-axis direction (e.g., the second direction) of the fourth fixing end portion 450 may be integrally connected to the first fixing end portion 420 and the second fixing end portion 430.

Because the first fixing end portion 420, the second fixing end portion 430, the third fixing end portion 440, and the fourth fixing end portion 450 are integrally and continuously formed along the edge portion of the heat dissipation portion 410, the heat conductive layer 401 of the heat dissipation portion 410 may be hermetically sealed from all directions, and the heat dissipation portion 410 may be firmly attached and fixed to the battery cell 100, the terrace 200, and the protection circuit module 300 from all directions.

The heat dissipation sheet 400 according to the present embodiment may further include a side surface protection portion 460. The side surface protection portion 460 may have a shape that protrudes in the X-axis direction (e.g., the first direction) from the third fixing end portion 440 in the development view of FIG. 4.

The heat dissipation sheet 400 may be formed in an order in which the second fixing end portion 430 is attached to a bottom surface of the terrace 200, the heat dissipation portion 410 is bent or folded up from the lower side to the upper side to form a C-shape so that an outer surface of the protection circuit module 300 is surrounded, and then the first fixing end portion 420 is attached to the battery cell 100.

Portions of the heat dissipation portion 410 and the third fixing end portion 440 together with the second fixing end portion 430 may be attached to the bottom surface of the terrace 200. In a state in which the portions of the heat dissipation portion 410 and the third fixing end portion 440 are attached to the bottom surface of the terrace 200, the side surface protection portion 460 may be disposed below the terrace 200, and may be disposed to protrude further in the Y-axis direction (e.g., the second direction) than one end portion in the Y-axis direction (e.g., the second direction) of the protection circuit module 300.

The side surface protection portion 460 may be bent or folded up from the terrace 200 to the protection circuit module 300 to be bonded to the first heat dissipation surface 333. The side surface protection portion 460 may surround an end portion in the X-axis direction (e.g., the first direction) of the protection circuit module 300, so that the end portion in the X-axis direction (e.g., the first direction) of the protection circuit module 300 is insulated and protected by the protective layer 403 and the flame-retardant layer 404.

The heat dissipation sheet 400 may be formed in an order in which the first fixing end portion 420 is attached to the battery cell 100, the heat dissipation portion 410 is bent or folded down from the upper side to the lower side to form a C-shape so that an outer surface of the protection circuit module 300 is surrounded, and then the second fixing end portion 430 is attached to a bottom surface of the terrace 200. In a state in which the second fixing end portion 430 is attached to the bottom surface of the terrace 200, the side surface protection portion 460 may be bent or folded up from the terrace 200 to the protection circuit module 300 to be bonded to an upper portion of the heat dissipation portion 410.

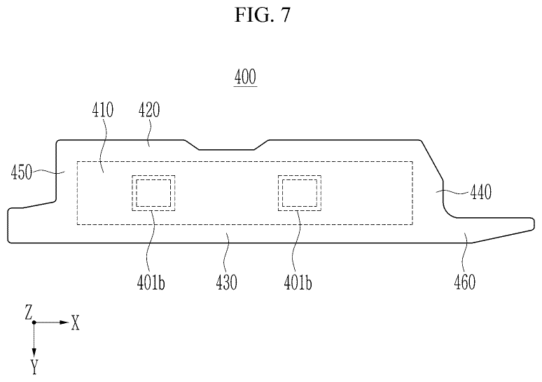

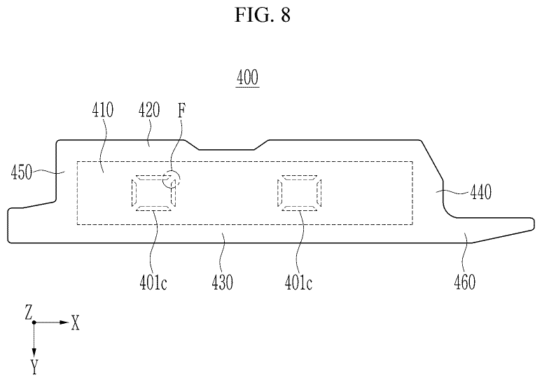

The short-circuit prevention portion 401a may have various shapes. This will be described with reference to FIG. 7 and FIG. 8.

FIG. 7 is a development view schematically showing components of the heat dissipation sheet according to one or more embodiments of the present disclosure, and FIG. 8 is a development view schematically showing components of the heat dissipation sheet according to one or more embodiments of the present disclosure.

Referring to FIG. 7, a short-circuit prevention portion 401b may be a single slit with a rectangular shape. That is, the heat conductive layer 401 may have a single slit with a rectangular shape. Accordingly, even if the insulating layer 402 of the portion facing the one end of the positive electrode lead 111 and the one end of the positive electrode lead connection plate 315 is destroyed, a current of the positive electrode lead 111 and a current of the positive electrode lead connection plate 315 may be prevented from being transferred to the heat conductive layer 401 so that a short circuit occurs by the slit.

Referring to FIG. 8, a short-circuit prevention portion 401c may be a structure in which a plurality of slits are disposed in a rectangular shape. That is, the heat conductive layer 401 may have a plurality of slits disposed in a rectangular shape. A fusible link F may be formed between the slits. Accordingly, if the insulating layer 402 of the portion facing the one end of the positive electrode lead 111 and the one end of the positive electrode lead connection plate 315 is destroyed, a current of the positive electrode lead 111 and a current of the positive electrode lead connection plate 315 may be transferred to the fusible link F, and in this case, the fusible link F may be broken so that the current of the positive electrode lead 111 and the current of the positive electrode lead connection plate 315 are prevented from being transferred to the heat conductive layer 401 so that a short circuit occurs.

Hereinafter, a heat dissipation effect of the rechargeable battery to which the heat dissipation sheet according to one or more embodiments of the present disclosure is applied will be described with reference to Table 1.

Table 1 shows a heat generation temperature of the protection circuit module of the rechargeable battery according to the embodiments of the present disclosure and a heat generation temperature of a protection circuit module of a rechargeable battery according to a comparative example.

In Table 1, the rechargeable battery according to Comparative Example 1 may be a rechargeable battery to which a heat dissipation sheet is not applied, and the rechargeable battery according to Comparative Example 2 may be a rechargeable battery to which a heat dissipation sheet including a short-circuit prevention portion is applied. A rechargeable battery according to Embodiment 1 may be a rechargeable battery to which the heat dissipation sheet including the short-circuit prevention portion is applied, and the short-circuit prevention portion may be an opening included in the heat conductive layer. A rechargeable battery according to Embodiment 2 may be a rechargeable battery to which the heat dissipation sheet including the short-circuit prevention portion is applied, and the short-circuit prevention portion may be a single slit having a rectangular shape of the heat conductive layer.

TABLE 1

| | Heat generation temperature of protection |
|---|---|
| | circuit module (° C.) |
| Comparative | 86 |
| Example 1 | |
| Comparative | 58 |
| Example 2 | |
| Embodiment 1 | 62 |
| Embodiment 2 | 59 |

As shown in Table 1, it may be confirmed that heat generated in the protection circuit module of each of the rechargeable batteries according to Comparative Example 2, Embodiment 1, and Embodiment 2 to which the heat dissipation sheet is applied is dissipated. It may be confirmed that the heat generated in the protection circuit module is dissipated even if the heat dissipation sheet includes the short-circuit prevention portion.

The rechargeable battery according to embodiments of the present disclosure may dissipate the heat generated in the protection circuit module by applying the heat dissipation sheet including the short-circuit prevention portion, and even if the insulating layer of the portion facing the one end of the positive electrode lead and the one end of the positive electrode lead connection plate and the insulating layer of a portion facing one end of the negative electrode lead and one end of the negative electrode lead connection plate are destroyed, a current of the positive electrode lead, a current of the positive electrode lead connection plate, a current of the negative electrode lead, and a current of the negative electrode lead connection plate may be prevented from being transferred to the heat conductive layer so that a short circuit occurs.

A charging specification of the rechargeable battery may be increased according to a customer's demand or a change in a market, and in this case, a size of the protection circuit module as well as a size of the rechargeable battery may be increased. As the size of the protection circuit module increases, heat generated from the protection circuit module also increases. Thus, it is necessary to provide a heat dissipation structure to the rechargeable battery. The heat dissipation structure should be able to perform heat dissipation for the protection circuit module and prevent a short circuit caused by a structural defect.

However, a technical problem to be solved by the present disclosure is not limited to the above, and other technical problems not mentioned may be clearly understood by those of ordinary skill in the art from a description of the present disclosure herein.

According to the embodiments of the present disclosure, a rechargeable battery may surround a protection circuit module and may include a heat dissipation sheet including a heat dissipation portion and a short-circuit prevention portion to improve a heat generation temperature of the protection circuit module and prevent a short circuit caused by a lead.

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

<Description of symbols>

| | |
|---|---|
| 1: rechargeable battery | 100: battery cell |
| 200: terrace | 300: protection circuit module |
| 310: substrate | 311: substrate body |
| 312: first surface | 313: second surface |
| 314: third surface | 320: field effect transistor |
| 330: molding member | 331: molding body |
| 332: fixing surface | 333: first heat dissipation surface |
| 334: second heat dissipation surface | 400: heat dissipation sheet |
| 401: heat conductive layer | |
| 401a, 401b, 401c: short-circuit preven- | |
| tion portion | |
| 402: insulating layer | 403: protective layer |
| 404: flame-retardant layer | 405: adhesive layer |
| 410: heat dissipation portion | 411: first heat dissipation portion |
| 412: second heat dissipation portion | |
| 413: third heat dissipation portion | |
| 414: fourth heat dissipation portion | 420: first fixing end portion |
| 420: second fixing end portion | 430: third fixing end portion |
| 450: fourth fixing end portion | |
| 460: side surface protection portion | |
| 500: fixing tape | 800: extension member |

What is claimed is:

1. A rechargeable battery, comprising:
a battery cell;
a terrace extending from the battery cell;
a protection circuit module on the terrace; and
a heat dissipation sheet covering the protection circuit module, wherein the heat dissipation sheet comprises:
a heat dissipation portion dissipating heat generated by the protection circuit module; and
a short-circuit prevention portion within the heat dissipation portion.

2. The rechargeable battery as claimed in claim 1, wherein the protection circuit module comprises:
a substrate comprising a first surface facing the terrace and a second surface opposite to the first surface;
a lead connection plate on the first surface; and
a transistor on the second surface.

3. The rechargeable battery as claimed in claim 2, wherein:
the battery cell further comprises an electrode lead, and
the electrode lead is connected to the lead connection plate.

4. The rechargeable battery as claimed in claim 3, wherein one end of the electrode lead and one end of the lead connection plate coincide with an extension line of a side surface of the substrate.

5. The rechargeable battery as claimed in claim 3, wherein the short-circuit prevention portion faces the one end of the electrode lead and the one end of the lead connection plate.

6. The rechargeable battery as claimed in claim 2, wherein the protection circuit module further comprises a molding member on the second surface, the molding member surrounding the transistor.

7. The rechargeable battery as claimed in claim 6, wherein the molding member comprises a molding body surrounding the transistor, wherein the molding body comprises:
a fixing surface fixed to the substrate;
a first heat dissipation surface on an opposite side of the fixing surface and facing the heat dissipation sheet; and
a second heat dissipation surface connecting the fixing surface to the first heat dissipation surface, the second heat dissipation surface facing the heat dissipation sheet.

8. The rechargeable battery as claimed in claim 7, wherein the heat dissipation portion comprises:
a first heat dissipation portion facing the first heat dissipation surface;
a second heat dissipation portion facing the second heat dissipation surface;
a third heat dissipation portion facing the side surface of the substrate; and
a fourth heat dissipation portion in contact with an outer surface of the terrace.

9. The rechargeable battery as claimed in claim 8, wherein the first heat dissipation portion, the second heat dissipation portion, the third heat dissipation portion, and the fourth heat dissipation portion are continuously connected.

10. The rechargeable battery as claimed in claim 8, wherein the first heat dissipation portion, the second heat dissipation portion, the third heat dissipation portion, and the fourth heat dissipation portion form a C-shape.

11. The rechargeable battery as claimed in claim 1, wherein the heat dissipation sheet comprises:
a heat conductive layer comprising a heat conductive material;
an insulating layer on an inner surface of the heat conductive layer, the insulating layer facing the protection circuit module; and
a protective layer on an outer surface of the heat conductive layer.

12. The rechargeable battery as claimed in claim 11, wherein the short-circuit prevention portion comprises an opening in the heat conductive layer.

13. The rechargeable battery as claimed in claim 11, wherein the short-circuit prevention portion comprises a single slit with a rectangular shape in the heat conductive layer.

14. The rechargeable battery as claimed in claim 11, wherein the short-circuit prevention portion comprises a plurality of slits in a rectangular shape, the plurality of slits being in the heat conductive layer.

15. The rechargeable battery as claimed in claim 14, wherein a fusible link is between the plurality of slits.

16. The rechargeable battery as claimed in claim 11, wherein the protective layer comprises:
a flame-retardant layer comprising a flame-retardant material; and
an adhesive layer between the flame-retardant layer and the heat conductive layer.

17. The rechargeable battery as claimed in claim 11, wherein the insulating layer has a first thickness and the protective layer has a second thickness thicker than the first thickness.

18. The rechargeable battery as claimed in claim 11, wherein the heat dissipation sheet further comprises:
a first fixing end portion fixed to the battery cell; and
a second fixing end portion fixed to the terrace.

19. The rechargeable battery as claimed in claim 18, wherein:
the heat dissipation portion comprises the heat conductive layer, the insulating layer, and the protective layer; and
the first fixing end portion and the second fixing end portion comprise the insulating layer and the protective layer.

20. The rechargeable battery as claimed in claim 1, wherein the heat dissipation portion has a rectangular shape.
